(19) United States
(12) Patent Application Publication
(10) Pub. No.: US 2025/0007251 A1
(43) Pub. Date: Jan. 2, 2025

(54) Low-Voltage Device

(71) Applicant: Future Systems Besitz GmbH, Rödental (DE)

(72) Inventors: Joram Masel, Küps (DE); Philipp Steinberger, Coburg (DE)

(21) Appl. No.: 18/710,369

(22) PCT Filed: Nov. 17, 2022
(86) PCT No.: PCT/EP2022/082210

§ 371 Date: May 15, 2024

(30) Foreign Application Priority Data
Nov. 18, 2021 (DE) 20 2021 106 291.6

(51) Int. Cl. H02B 1/30; H01H 71/00; H01H 71/04; H10K 77/10; H10K 102/00

(52) U.S. Cl. CPC H02B 1/306; H01H 71/04; H01H 2071/006; H10K 77/111; H10K 2102/311

(57) ABSTRACT

A low-voltage device for electrical distribution boards and switching cabinet installations with components comprised in a housing of the low-voltage device, wherein the housing of the low-voltage device comprises a mounting interface for mounting the housing to a corresponding mating interface of the electrical distribution board or the switching cabinet or to a component installed in the electrical distribution board or to a component installed in the switching cabinet; a display housing portion of the housing, which is provided for a display unit of the low-voltage device and comprises one or more flexibly formed bendable and foldable display units, wherein the flexible display unit is provided bent to fit a contour of the display housing portion of the housing of the low-voltage device or is provided folded on the display housing portion of the housing of the low-voltage device and can be unfolded there to enlarge a display area of the display unit.

### TECHNICAL FIELD OF THE INVENTION

The invention relates to a low-voltage device for electrical distribution boards and switching cabinet installations.

### BACKGROUND OF THE INVENTION

DE 10 2011 006 112 A1 describes a low-voltage device with a switch housing and a display screen which is movable relative to the switch housing. The flat display screen is located on the inside or on the outside of a flat, inflexible support which can be pivoted about a pivot axis relative to the switch housing. Together with the display screen, the flat support can be optionally inserted into a slot in the switch housing after pivoting about the pivot axis.

A switching cabinet contains electrical and/or electronic components for a process plant, for example a production plant. A switching cabinet can comprise various types of low-voltage devices to which electrical loads can be connected. Low voltage is generally defined as alternating voltages up to around 1000 volts and direct voltages up to around 1500 volts. The low-voltage devices can fulfill different functions for open-loop or closed-loop controlling connected loads. The various low-voltage devices can be mounted on current busbars, for example, to distribute electrical power. Low-voltage devices are primarily mounted in switching cabinets or small distribution board housings. Such low-voltage devices include, for example, fuse switch disconnectors or motor control units. The use of low-voltage devices in automation plants requires a relatively long service life of the respective low-voltage devices as well as a high level of reliability to prevent production downtimes.

Conventional low-voltage devices have simple display elements, such as LEDs, to indicate a fault condition of the low-voltage device. Due to the limited space available within a switching cabinet or a small distribution board housing, conventional low-voltage devices have simple display units or indicators, or displays with small display areas so that only simple indicators can be shown on them. The display of further information regarding the switching cabinet or the corresponding low-voltage device, such as operating instructions, is not possible with such simple display units. Due to their diverse technical functions, low-voltage devices have housings with diverse shapes. In many low-voltage devices, the housings sometimes have strongly curved contours or surfaces due to the special technical functionality of the corresponding low-voltage device.

### SUMMARY OF THE INVENTION

It is therefore an objective of the present invention to create a low-voltage device for electrical distribution boards or switching cabinet installations which is capable of providing a user with complex information via a user interface without requiring additional installation space within a switching cabinet housing or a small distribution board housing.

According to the invention, this task is solved by a low-voltage device for electrical distribution boards and switching cabinet installations with components comprised in a housing of the low-voltage device, wherein the housing of the low-voltage device comprises:
a mounting interface for mounting the housing of the low-voltage device to a corresponding mating interface of the electrical distribution board or to a switching cabinet or to a component installed in the electrical distribution board or a component installed in the switching cabinet; and
a display housing portion of the housing, which is provided for a display unit of the low-voltage device and comprises a flexibly formed, bendable and/or foldable display unit, wherein the flexible display unit is provided bent to fit a contour of the display housing portion of the housing of the low-voltage device or is provided folded on the display housing portion of the housing of the low-voltage device and can be unfolded there to enlarge a display area of the display unit.

In one possible embodiment, the flexible display unit of the low-voltage device is fixedly or removably attached to a non-planar or curved contour of the housing. In an alternative embodiment, the flexible display unit is provided folded on the display housing portion of the housing and can be unfolded manually by a user or automatically to enlarge a display area of the display unit.

The flexible display unit preferably comprises a display layer with a thickness of less than 0.1 mm. This display layer is preferably located on a lower protective, or support, layer. In addition, there is a preferably another transparent protective layer at the front of the display layer.

In one possible embodiment of the low-voltage device according to the invention, the flexible display unit comprises a display layer with a bending radius of less than 1.0 mm.

In another possible embodiment of the low-voltage device according to the invention, the flexible display unit comprises a touch-sensitive display layer for user input from a user and for displaying information to a user.

In a further possible embodiment of the low-voltage device according to the invention, the housing of the low-voltage device comprises a mounting interface for mounting the low-voltage device on at least one current busbar of a current busbar system of the switching cabinet or the electrical distribution board and for electrically contacting the current busbar.

In another possible embodiment of the low-voltage device according to the invention, the housing of the low-voltage device comprises a mounting interface for mounting the low-voltage device on a top-hat rail or on a mounting plate of the switching cabinet or the electrical distribution board.

In another possible embodiment of the low-voltage device according to the invention, the flexible display unit is detachably attached to a data interface provided on the display housing portion of the housing of the low-voltage device and/or to a power supply interface.

In another possible embodiment of the low-voltage device according to the invention, the display housing portion of the housing of the low-voltage device consists of a transparent material in which the flexible display layer of the display unit is embedded.

In one possible embodiment of the low-voltage device according to the invention, the flexible display layer comprises an OLED display layer.

In a further possible embodiment of the low-voltage device according to the invention, the components of the low-voltage device comprised in the housing of the low-voltage device comprise power components which generate heat or warmth during operation of the low-voltage device.

In another possible embodiment of the low-voltage device according to the invention, the display housing portion of the housing of the low-voltage device provided for the flexible display unit is thermally insulated from the power components of the low-voltage device by a thermal insulation to protect the flexible display unit from heat.

In a further possible embodiment of the low-voltage device according to the invention, the components comprised in the housing of the low-voltage device comprise a control unit which exchanges data with the flexible display unit provided on the display housing portion via a data interface provided in the display housing portion of the housing of the low-voltage device.

In another possible embodiment of the low-voltage device according to the invention, the components comprised in the housing of the low-voltage device comprise a transceiver which provides a wireless communication link with a control unit of the switching cabinet or of the electrical distribution board via a transceiver of the switching cabinet or the electrical distribution board.

In another possible embodiment of the low-voltage device according to the invention, a camera is integrated into the display surface of the flexible display unit.

Using this camera, a control unit of the low-voltage device can observe or monitor the immediate surroundings of the low-voltage device within the switching cabinet housing or small distribution board housing.

In another possible embodiment of the low-voltage device according to the invention, the housing of the low-voltage device consists of an electrically insulating and fireproof material.

In one possible embodiment of the low-voltage device according to the invention, the low-voltage device comprises a switch disconnector with fuses.

In another possible embodiment of the low-voltage device according to the invention, the low-voltage device comprises a fuse switch disconnector.

In another possible embodiment of the low-voltage device according to the invention, the low-voltage device comprises a switch disconnector.

In another possible embodiment of the low-voltage device according to the invention, the low-voltage device comprises a circuit breaker.

In another possible embodiment of the low-voltage device according to the invention, the low-voltage device comprises a motor control unit.

In another possible embodiment of the low-voltage device according to the invention, the low-voltage device comprises a power supply unit.

In another possible embodiment of the low-voltage device according to the invention, the low-voltage device comprises a frequency converter.

In another possible embodiment of the low-voltage device according to the invention, the low-voltage device comprises a power feed-in module.

In another possible embodiment of the low-voltage device according to the invention, a data and/or control interface is provided in the housing of the low-voltage device for connecting a capacitive load, an inductive load or a resistive load to the low-voltage device.

In a further possible embodiment of the low-voltage device according to the invention, the information displayed on the display unit of the low-voltage device comprises:
status information of the low-voltage device or other low-voltage devices mounted in the switching cabinet or distribution board,
configuration details of the low-voltage device or other low-voltage devices mounted in the switching cabinet or distribution board,
measurement data of the low-voltage device or other low-voltage devices mounted in the switching cabinet or distribution board,
a circuit diagram of the low-voltage device and/or another low-voltage device mounted in the switching cabinet or distribution board or a circuit diagram of the low-voltage devices mounted in the switching cabinet or distribution board,
operating instructions for operating the low-voltage device or the distribution board or switching cabinet,
a service number for a maintenance service for servicing the switching cabinet or distribution board and/or the low-voltage device or further low-voltage devices within the switching cabinet or distribution board and/or status information of at least one load connected to the low-voltage device.

In another possible embodiment of the low-voltage device according to the invention, the unfolded flexible display unit is pivotably attached to the housing of the low-voltage device.

In another possible embodiment of the low-voltage device according to the invention, an unfolded flexible display unit of the low-voltage device forms, together with another unfolded flexible display unit of a low-voltage device mounted adjacent to it on the rail of the switching cabinet or distribution board, a composite display unit with a large display area.

In one possible embodiment, the low-voltage device comprises a control unit integrated in the housing, which is connected to the display unit and to a camera via a data and control interface.

In one possible embodiment, the control unit comprises an artificial intelligence module for classifying the image data provided by the camera.

In another possible embodiment of the low-voltage device according to the invention, the display unit of the low-voltage device is connected via a wired or wireless bus system of the switching cabinet or distribution board with other devices of the switching cabinet or distribution board for data transmission.

In another possible embodiment of the low-voltage device according to the invention, the display unit of the low-voltage device is connected to an intranet of an automation system and/or to the Internet via a gateway.

In another possible embodiment of the low-voltage device according to the invention, the display unit is coupled to an acoustic user interface of the low-voltage device and/or the switching cabinet or distribution board.

In another possible embodiment of the low-voltage device according to the invention, the flexible display unit comprises a flexible rear support layer for supporting the display layer of the display unit and a flexible front transparent protective layer for protecting the display layer of the display unit.

In another possible embodiment of the low-voltage device according to the invention, the display unit can be folded along at least one folding line with a certain bending radius.

According to a further aspect, the invention provides a switching cabinet with rails for mounting various low-voltage devices according to the first aspect of the invention.

According to a further aspect, the invention provides an electrical distribution board comprising low-voltage devices according to the first aspect of the invention.

### BRIEF DESCRIPTION OF THE DRAWINGS

In the following, possible embodiments of the low-voltage device according to the invention for mounting in a switching cabinet or an electrical distribution board are explained in more detail with reference to the attached figures.

Therein are showing:

FIG. 1 a perspective view of a simple embodiment of a low-voltage device according to the invention;

FIG. 2 a further view of a possible embodiment of a low-voltage device according to the invention;

FIG. 3 a schematic sectional view to illustrate the functionality of an exemplary low-voltage device;

FIGS. 4A, 4B sectional view to show different embodiments of the low-voltage device according to the invention;

FIGS. 5A, 5B views illustrating a possible embodiment of a low-voltage device according to the invention;

FIGS. 6A, 6B further view to illustrate a further embodiment of the low-voltage device according to the invention;

FIG. 7 a further view illustrating a further embodiment of the low-voltage device according to the invention;

FIG. 8 a depiction of an embodiment of a low-voltage device according to the invention;

FIG. 9 a depiction of a further embodiment of a low-voltage device according to the invention.

### DETAILED DESCRIPTION OF EMBODIMENTS

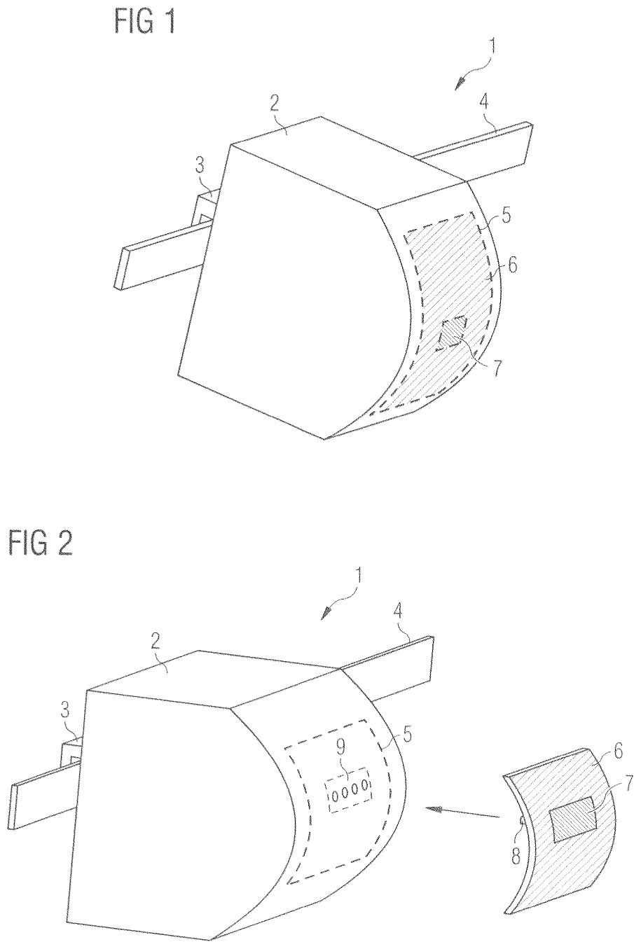

FIG. 1 shows a perspective view of a low-voltage device 1 according to the invention, which can be mounted, for example, in an electrical distribution board or in a switching cabinet. The low-voltage device 1 can provide different technical functions within the switching cabinet or electrical distribution board. The low-voltage device 1 comprises various components that are mounted in a housing 2. The housing 2 of the low-voltage device 1 can be made of an electrically insulating and fireproof material.

In the embodiment shown in FIG. 1, the low-voltage device 1 comprises an electromechanical mounting interface 3 on its rear side for mounting the housing 2 to a corresponding mating interface of the electrical switching cabinet or distribution board or to a component installed in the electrical distribution board or switching cabinet. This component installed in the switching cabinet is, for example, an electromechanical adapter. In the embodiment shown in FIG. 1, the switching cabinet or distribution board contains a horizontally mounted rail 4, which is attached to a mounting platform. However, the rail 4 can also be mounted vertically. In the embodiment shown in FIG. 1, the rail 4 is a current busbar. Alternatively, the housing 2 of the low-voltage device 1 can also be mounted on a top-hat rail or a mounting plate of the distribution board or switching cabinet. A mounting rail or top-hat rail with a top-hat profile is a universal support made from a sheet metal profile and can be used to attach electrical equipment to a distribution box, switching cabinet or junction box. Different types of components can be pushed on from the side or locked in place onto such a mounting or top-hat rail.

In another possible embodiment, the housing 2 of the low-voltage device 1 can be attached directly to a mounting plate of the switching cabinet or distribution board using fastening means, for example screws. The low-voltage device 1 is preferably mounted on the current busbar, the top-hat rail or on the mounting plate without any tools, by directly placing and locking it in position.

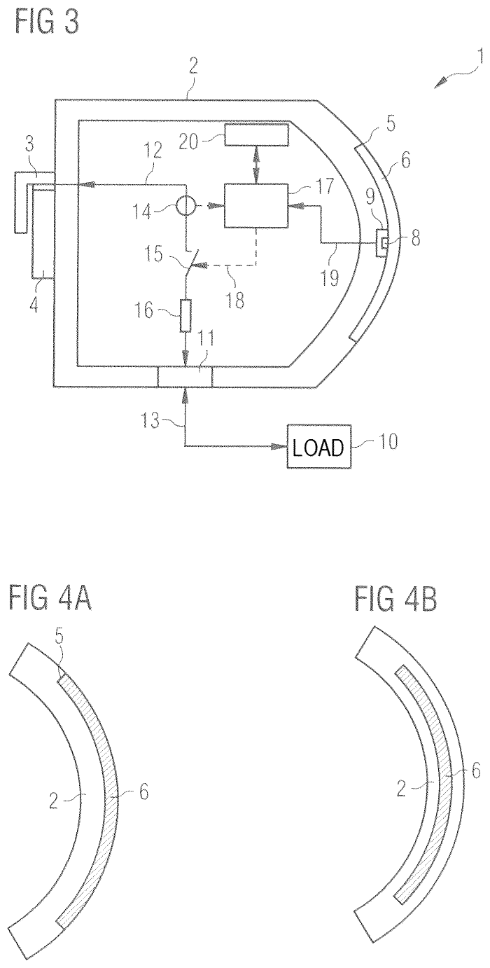

In the embodiment shown in FIG. 1, the current busbar 4 is not only used for mechanical mounting of the low-voltage device 1, but also carries an electrical current that can be supplied to the low-voltage device 1 via electrical contacts at the mounting interface 3. Load units 10 can be connected to the low-voltage device 1 via further interfaces 11, as also shown in FIG. 3.

The housing 2 of the low-voltage device 1 comprises a display housing portion 5, which is provided for a display unit 6 of the low-voltage device 1. The display housing portion 5 comprises a flexible, bendable and/or foldable display unit 6. The flexible display unit 6 is provided bent to fit a contour of the display housing portion 5 of the housing 2 of the low-voltage device 1. The shape of the bendable display unit 6 thus adapts to the curved contour of the display housing portion 5, as shown schematically in FIG. 1.

In one possible embodiment, the flexible display unit 6 comprises a display layer which is provided, for example, on a support and protective layer.

In one possible embodiment, the display layer has a thickness of less than 0.1 mm. There can be a protective layer on both sides of the display layer. The rear protective layer also serves as a support layer for the display layer, for example. The front transparent protective layer protects the display layer of the display unit 6 from the environment within the automation system, in particular from mechanical influences. Furthermore, the front transparent protective layer provides protection against dust and moisture.

The rear support layer and the front transparent protective layer of the flexible display unit 6 preferably each consist of a bendable elastic material which allows folding and unfolding the display unit 6 along a straight folding line FL with a specific bending radius R. The rear support layer may have a thickness of less than 1 mm. In a preferred embodiment, the flexible display unit 6 shown in FIG. 1 comprises a touch-sensitive display layer for input by a user and for displaying information to a user.

In a preferred embodiment, the flexible display layer of the display unit 6 comprises an OLED (Organic Light-Emitting Diode) layer. The OLED display layer comprises organic light-emitting diodes and a luminous thin-film component made of organic semiconducting materials.

Various electrical, electronic and mechanical parts or components can be located in the housing 2 of the low-voltage device 1 in order to provide the corresponding functionality of the low-voltage device 1.

In one possible embodiment, power components that generate heat or warmth during operation of the low-voltage device 1 or when short-circuit currents or overvoltages occur are arranged in the housing 2 of the low-voltage device 1. In a preferred embodiment of the low-voltage device 1 according to the invention, the display housing portion 5 of the housing 2 of the low-voltage device 1 provided for the flexible display unit 6 comprises thermal insulation, for example a thermal insulation layer. This thermal insulation provides thermal protection of the flexible display unit 6 against the heat or warmth generated by the power components contained in the housing 2 of the low-voltage device 1 during operation of the low-voltage device 1.

In a further embodiment, the rear support and protective layer of the display unit 6 is provided on a heat-insulating layer of the display unit 6, which protects the display layer of the display unit 6 against heat or warmth within the housing 2, which is generated by power components of the low-voltage device 1 during operation of the low-voltage device or when short circuits or overvoltages occur. Alternatively, the support and protective layer of the display unit 6 consists of a heat-insulating material. In a further embodiment, both the housing portion 5 and the display unit 6 have a thermally insulating layer.

In one possible embodiment of the low-voltage device 1, its housing 2 comprises a temperature sensor that monitors the temperature T inside the housing 2. The temperature T can be displayed on the display unit 6. If the temperature value exceeds a temperature threshold value, the user can be prompted via the display unit 6 to remove the display unit 6 from the housing portion 5 to protect it and/or activate a locally provided cooling system, such as a fan. Activating the cooling can also be done automatically when a temperature threshold is exceeded.

Furthermore, the components comprised in the housing 2 of the low-voltage device 1 may also include electronic components, in particular a control unit 17 or controller, as shown in FIG. 3. The control unit 17 comprised in the housing 2 can exchange data with the flexible display unit 6 provided on the display housing portion 5 of the low-voltage device 1 via a display data interface 9 provided in the display housing portion 5 of the low-voltage device 1, as shown schematically in FIG. 2.

In addition to the control unit 17, a transceiver 20 can also be arranged in the housing 2 of the low-voltage device 1 in one possible embodiment. This transceiver 20 establishes a wireless communication link with a transceiver of the switching cabinet or the electrical distribution board to a control unit of the switching cabinet or distribution board. In this way, the control unit 17 integrated in the housing 2 of the low-voltage device 1 can exchange data with the control unit of the switching cabinet or distribution board, in particular sensor or measurement data, which can be displayed to a user on the display unit 6 of the low-voltage device 1.

In one possible embodiment, at least one camera 7 is integrated into the display surface of the flexible display unit 6 shown in FIG. 1. When the low-voltage device 1 is mounted on a rail of a switching cabinet or distribution board, the camera 7 preferably points forwards towards a switching cabinet door of the switching cabinet or distribution board. The camera 7 integrated in the display unit 6 makes it possible to monitor the immediate mounting environment of the low-voltage device 1 inside the switching cabinet or distribution board in its field of view. For this purpose, a reflective or mirroring surface can preferably be provided on the inside of the switching cabinet door. If several low-voltage devices 1 are mounted next to each other on a rail, for example on a current busbar 4, the camera 7 of a low-voltage device 1 can detect which other low-voltage devices 1 are installed in the immediate mounting environment of the low-voltage device 1. In addition, the camera 7 integrated in the display surface of the display unit 6 can also monitor whether display elements of the other low-voltage devices 1 are emitting optical signals. For example, if an LED of an adjacent low-voltage device 1 lights up, this can be detected by the camera 7 of the display unit 6. FIG. 1 schematically shows the camera 7 integrated in the display surface. Several optically sensitive surfaces or cameras 7 can also be integrated into the display surface of the display unit 6. The camera 7 integrated in the display unit 6 is preferably connected to a control unit 17 inside the housing 2 of the low-voltage device 1 via a data interface.

In addition, a further data and control interface 11 can be provided in the housing 2 of the low-voltage device 1 for connecting a capacitive load, an inductive load or a resistive load to the low-voltage device 1. The inductive load is an electric motor, for example. The resistive load is, for example, a heating element or the like. This data and control interface 11 is located, for example, on an underside of the housing 2 of the low-voltage device 1 shown in FIG. 1, as shown in FIG. 3. In one possible embodiment, the load 10 is connected to the data and control interface 11 of the low-voltage device 1 via electrical cables 13. In one possible embodiment, the camera 7 of the low-voltage device 1 serves to monitor a correct connection of the wiring cables 13 that connect the load 10 to the data and control interface 9. If, for example, an electrical connection cable 13 of a power phase L for the load 10 is missing, this can be detected automatically by the control unit 17 of the low-voltage device 1 after evaluating the camera image, which is provided by the camera 7, and, if necessary, reported to a control unit of the switching cabinet or distribution board via a data interface. In one possible embodiment, the camera images from the camera 7 are transmitted to a control unit of the switching cabinet or distribution board or to a server via a wireless communication link and evaluated there. In this embodiment, the control unit of the switching cabinet or distribution board or the server preferably comprises an image recognition unit for evaluating camera images or image data and/or a correspondingly trained artificial neural network (CNN, RNN).

In one possible embodiment, various low-voltage devices 1 communicate with each other via a wireless communication link. For example, low-voltage devices 1 that do not have their own display unit 6 can communicate sensor data or other information via the wireless communication link to the low-voltage device 1 shown in FIG. 1, which displays the information received on its display unit 6 to a user.

In one possible embodiment, the low-voltage device 1 shown in FIG. 1 is a display low-voltage device specialized in display functions, which is designed to display information on a curved display surface of the housing 2.

On the flexible display unit 6 of the low-voltage device 1, different items of information can be displayed. For example, in one possible embodiment of the flexible display unit 6, status information of the low-voltage device 1 or of other low-voltage devices 1 or other devices mounted in the switching cabinet or distribution board are displayed to a user.

In addition, in one possible embodiment, the flexible display unit 6 can visually display configuration information or parameters of the low-voltage device 1 or other low-voltage devices 1 or other devices mounted in the switching cabinet or distribution board to a user.

Furthermore, measurement data from the low-voltage device 1 or other devices mounted in the switching cabinet can also be displayed on the display unit 6.

The flexible display unit 6 of the low-voltage device 1 according to the invention is also capable of visually displaying complex information to a user. For example, in one possible embodiment, a circuit diagram or operating instructions for the low-voltage device 1 and/or another low-voltage device 1 mounted in the switching cabinet or distribution board can be displayed using the flexible display unit 6.

In addition, service numbers for a maintenance service for servicing the switching cabinet and/or the low-voltage device 1 or other devices within the switching cabinet or distribution board can also be displayed, for example. These service numbers include, for example, a telephone number. Furthermore, IP addresses and websites can also be displayed as service numbers.

In one possible embodiment, a link (Uniform Resource Locator URL) to a service web page is displayed on the touch-sensitive display unit 6 as soon as a certain operating status of the low-voltage device 1 or the switching cabinet is detected. By manually pressing the displayed link, the user is taken directly to the corresponding service page, which provides the user with the necessary information for the operating status in question. Furthermore, in one possible embodiment, the flexible display unit 6 of the low-voltage device 1 can also be used to display status information or other data of a load 10 connected to the low-voltage device 1. This load 10 is, for example, a capacitive, resistive or inductive load. For example, an electric motor connected to a motor control unit 1 can supply maintenance information to the low-voltage device or the motor starter 1, which is displayed to the user via the display unit 6. The display unit 6 of the low-voltage device 1 can be connected via a wired or wireless bus system of the switching cabinet or distribution board to other devices of the switching cabinet, in particular to other low-voltage devices 1 of the switching cabinet, to carry out data transmission. For example, the display unit 6 of the low-voltage device 1 can be connected to an intranet of an automation system via a communication link. In addition, the display unit 6 of the low-voltage device 1 can also be connected to the Internet via a gateway.

In one possible embodiment, the display unit 6 is coupled to an acoustic user interface of the low-voltage device 1 and/or the switching cabinet or distribution board. In this way, it is possible to output additional information or warning signals acoustically to a user. Furthermore, a user can also use the acoustic user interface to enter inputs or commands via a microphone, wherein the information entered is also displayed to the user via the display unit 6 so that the user can check whether their acoustic input has been understood correctly. This is particularly helpful for the user in a noisy production environment of an automation system.

FIG. 2 schematically shows an embodiment of a low-voltage device 1 according to the invention with a flexible display unit 6. In the embodiment shown in FIG. 2, the flexible display unit 6 can be placed on an associated display housing portion 5 provided on the housing 2. The shape of the flexible display unit 6 adapts to the contour or curvature of the display housing portion 5 of the housing 2, as shown schematically in FIG. 2. The flexible display unit 6 preferably comprises a data interface 8, which is inserted into or can be connected to a corresponding data interface 9 within the housing portion 5. In addition to the data interface 9, a power supply interface can also be provided for the electrical power supply of the flexible display unit 6. The flexible display unit 6 is preferably removably attached to the data interface provided on the display housing portion 5 of the housing 2 of the low-voltage device 1 and/or to the associated power supply interface. The user can manually insert the flexible display unit 6 into the display housing portion 5. 5 of the housing 2. In this way, a user has the option of equipping a low-voltage device 1 with a flexible display unit 6 if desired. The attaching of the flexible display unit 6 is therefore undoable and can be designed in different ways. For example, the flexible display unit 6 is temporarily attached to the display housing portion 5 of the housing 2 using magnets. Alternatively, the flexible display unit 6 can also be attached to the display housing portion 5 using a Velcro fastener, for example.

In a preferred embodiment, the flexible display unit 6 remains switched on after being removed from the housing 2 of the low-voltage device 1. Data can be exchanged between the display unit 6 and the low-voltage device 1 via a wired or wireless data connection. Power is supplied to the display unit 6 being removed from the housing 2 of the low-voltage device 1 via a power connection or by an energy storage unit integrated in the display unit 6. In another possible embodiment, the flexible display unit 6 maybe manually detached from the display housing portion 5 by a user and placed on a display housing portion 5 of another low-voltage device 1 within the switching cabinet. In doing so, the flexible display unit 6 adapts to the contour or shape of the other low-voltage device 1.

The removable flexible display unit 6 shown in FIG. 2 may in turn have an integrated camera 7, which provides camera images of the mounting environment of the low-voltage device 1.

FIG. 3 shows a sectional view through a possible embodiment of a low-voltage device 1 according to the invention. FIG. 3 shows a sectional view through a housing wall of the housing 2 of the low-voltage device 1. On the right-hand side shown in FIG. 3, there is a display housing portion 5 for holding a flexible display unit 6, the contacts 8 of which are inserted into corresponding contacts of a data and/or power supply interface 9 of the low-voltage device 1. In the example shown, the housing 2 of the low-voltage device 1 is mounted on a current busbar 4 of the switching cabinet or distribution board via an electromechanical mounting interface 3. The current busbar 4 offers the possibility of distributing a direct or alternating current within the distribution board or switching cabinet. As shown schematically in FIG. 3, a load 10 is connected to a data and/or control interface 11 on the underside of the housing 2. The load 10 is, for example, a resistive load, an inductive load or a capacitive load. The current tapped from the current busbar 4 can be supplied to the load 10 for power supply via an internal power supply path 12 and via power connection lines 13. In the example shown in FIG. 3, additional components can be provided inside the housing 2, for example a current sensor 14, a switch 15 or a fuse 16. In the example shown in FIG. 3, a control unit 17 is integrated in the housing 2, which controls the switch 15 comprised in the power supply path 12 via an internal control line 18. In addition, the control unit 17 is connected to the data and power supply interface of the display unit 6 via internal power and data lines 19. In addition to the current sensor 14 shown in FIG. 3, a voltage sensor supplying a voltage signal can also be provided for measuring the voltage applied to the internal power supply path 12. In one possible embodiment, the analog measurement signals are converted into measurement data by analog-to-digital converters not shown, which are in one possible implementation temporarily stored in an internal data storage of the control unit 17. In addition, the data generated by the display unit 6 may also be temporarily stored in the internal data storage of the control unit 17. This data from the flexible display unit 6 indicates, for example, which area of the display surface has been touched by the fingertip of a user's finger. This data can be translated into corresponding input commands. In addition, the camera 7 integrated in the display surface provides image data that can be temporarily stored in a data storage of the memory unit 17. Furthermore, the control unit 17 can be connected to an integrated transceiver 20 to transmit the buffered data to an external control unit, in particular to a control unit of a switching cabinet or distribution board. If a short circuit occurs within the power supply path, the integrated sensor element 14 supplies a corresponding measurement signal, which is evaluated to detect a short circuit. As soon as a short circuit is detected, the control unit 16 can automatically open the integrated switch to interrupt the protective current and thereby protect the load 10. The detected short circuit is displayed to the user on the flexible display unit 6. As soon as the cause of the short circuit has been rectified by the user, the user can, for example, press the touch-sensitive display surface of the display unit 6 at a corresponding position in order to cause the integrated switch 15 to be closed by the control unit 17.

The low-voltage device 1 shown in FIG. 3 is merely exemplary, i.e. other low-voltage devices may comprise completely different parts and components. The provision of the integrated control unit 17 is optional. In an alternative embodiment, the data of the flexible display unit 6 can be transmitted directly to an external control unit of the switching cabinet or distribution board via a transceiver 20. In addition, the display unit 6 can also receive display data directly via a transceiver from an external control unit of the cabinet or distribution board. Furthermore, in another embodiment, data or information to be displayed can also be transmitted via the current busbar 4 of the switching cabinet or distribution board by means of powerline communication PLC and displayed on the display unit 6. In one possible embodiment, the camera 7 integrated in the display unit 6 can also provide camera images for detecting certain switch events within the switching cabinet or distribution board. For example, arcs can occur inside the switching cabinet, the light from which can be recognized on camera images. Furthermore, in one possible embodiment, the camera images from the camera 7 integrated in the display unit 6 can be used to automatically detect the position or location at which the low-voltage device 1 is mounted within the switching cabinet or electrical distribution board.

In a further embodiment, a camera 7 is provided that generates thermal images. A camera 7 can therefore be integrated into the display surface of the flexible display unit 6, which generates camera images in the visible frequency range or in an invisible frequency range, in particular in the infrared frequency range, which are evaluated to detect switch events and/or local heat development within the switching cabinet.

Based on the shape and other features of the other low-voltage devices 1 within the switching cabinet or distributor, pattern recognition by a control unit of the switching cabinet or distribution board can be used to recognize which kind or type of low-voltage devices 1 are mounted at which position within the switching cabinet or distribution board. For this purpose, a control unit 17 of the switching cabinet or distribution board can have a trained artificial intelligence module, in particular an artificial neural network (CNN), which allows recognizing patterns of objects within the switching cabinet or distribution board or classifying the images or image data received from the cameras 7 of the low-voltage devices 1 accordingly.

FIGS. 4A, 4B show possible embodiments of a flexible display unit 6 that can be installed in the low-voltage device 1. In the embodiment shown in FIG. 4A, the display unit 6 is attached to the outside of the corresponding display housing portion 5 of the housing 2. The display unit 6 can, in one possible embodiment, be provided in a fixed or non-removable manner on the corresponding housing portion 5. In this embodiment, for example, the display unit 6 is glued to the display housing portion 5. Alternatively, the flexible display unit 6 may also be detachably attached to the display housing portion 5 of the housing 2, as shown schematically in FIG. 2.

FIG. 4B shows a further variant of an embodiment in which the flexible display unit 6 is embedded within the housing 2. Here, the housing 2 at the corresponding display housing portion 5 preferably consists of a transparent material in which the flexible display layer of the display unit 6 is embedded. The flexible display layer preferably comprises an OLED display layer.

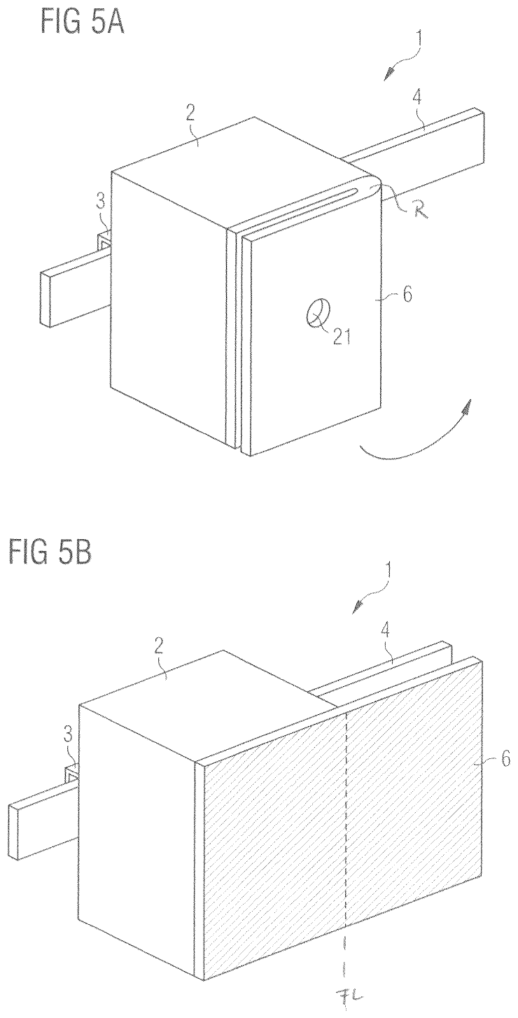

FIGS. 5A, 5B show a further variant of an embodiment of the low-voltage device 1 according to the invention. In the embodiment shown in FIGS. 5A, 5B, the flexible display unit 6 is provided on a display housing portion 5 of the housing 2 in folded form and can be unfolded by a user to enlarge a display area of the display unit 6, as shown in FIG. 5B. In the embodiment shown in FIGS. 5A, 5B, the unfolded display is twice as large as the front surface of the housing 2 of the corresponding low-voltage device 1.

In one possible embodiment, the flexible display unit 6, as shown in FIG. 5A, may comprise a simple display element, for example a light-emitting diode 21, which indicates to the user that the flexible display unit 6 should be unfolded to display information. Once the display unit 6 has been unfolded, it can display various complex items of information regarding the operating status of the low-voltage device 1 itself or other devices of the switching cabinet. The resolution of the display surface is, for example, 1440×1920 pixels in one possible implementation. The active display layer preferably has a thickness of less than 0.1 mm. In addition, the bending radius R of less than 1.0 mm allows to unfold the display unit 6 in a space-saving manner from the non-unfolded state according to FIG. 5A. In the folded state according to FIG. 5A, the display unit 6 is additionally protected against environmental influences within the automation system, in particular against dust and moisture. Furthermore, the not unfolded state provides protection of the display surface against mechanical influences or ambient heat.

In a preferred embodiment, the flexible display unit 6 shown in FIGS. 5A, 5B comprises a touch-sensitive display layer for input by a user and for displaying information to a user. In a preferred embodiment, the flexible display layer of the display unit 6 comprises an OLED (Organic Light-Emitting Diode) layer. The OLED display layer comprises organic light-emitting diodes and a luminous thin-film component made of organic semiconducting materials.

The flexible display unit 6 can have a rear support layer that protects and supports the display layer. A further transparent protective layer may in turn be provided on the display layer. Both the in general opaque rear support layer and the transparent front protective layer of the display unit 6 consist of a flexible bendable material, so that the display unit 6 can be folded and unfolded again at one or more points along an associated folding line FL with a specific bending radius R.

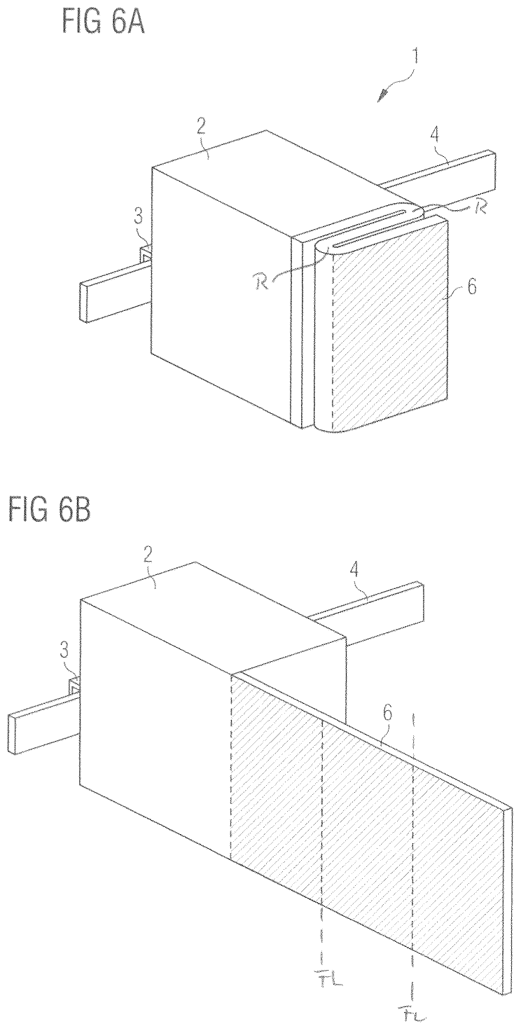

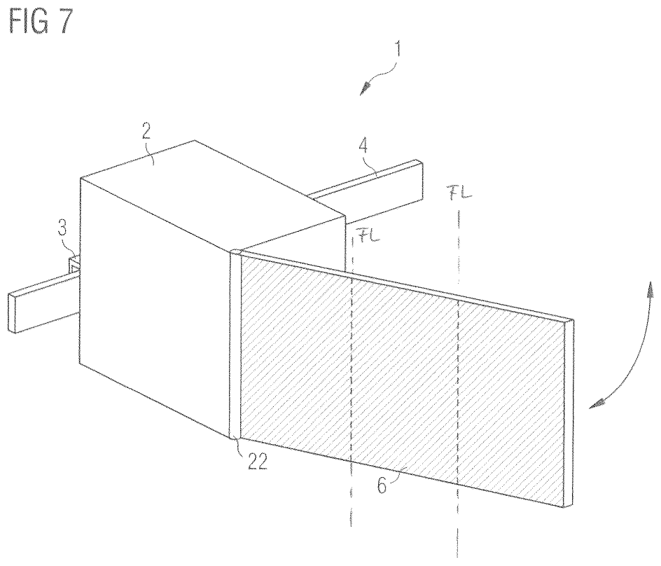

Due to its flexibility and the at least one support layer consisting of an elastic material, the contiguously-formed display unit 6 can be folded at one or more points with a certain bending radius R and then unfolded again without this being recognizable to a user in the unfolded state. Only in the unfolded state does the display unit 6 form a flat plane, as shown in FIGS. 5B, 6B. In another possible embodiment, as shown in FIG. 7, the flexible display unit 6 may also be unfoldable several times. This can further increase the size of the display area for presenting information to the user. Furthermore, in the embodiment shown in FIG. 7, the flexible display unit 6 is pivotably mounted on the housing 2 of the low-voltage device 1 on a pivot joint 22. In the embodiment shown, this makes it possible to additionally swivel the unfolded display unit 6 within the distribution board or switching cabinet in a horizontal plane parallel to the horizontally installed rails 4, so that a user can easily operate the display unit 6 during their activity within the switching cabinet accordingly. If, for example, a user is carrying out maintenance or repair work inside the switching cabinet or distribution board, they can pivot the pivotable unfolded display unit 6 according to their working position in order to be better able to see the information displayed on the display unit 6, such as repair instructions. In one possible implementation, the unfolded flexible display unit 6 is also pivotable in several directions or around different axes in space.

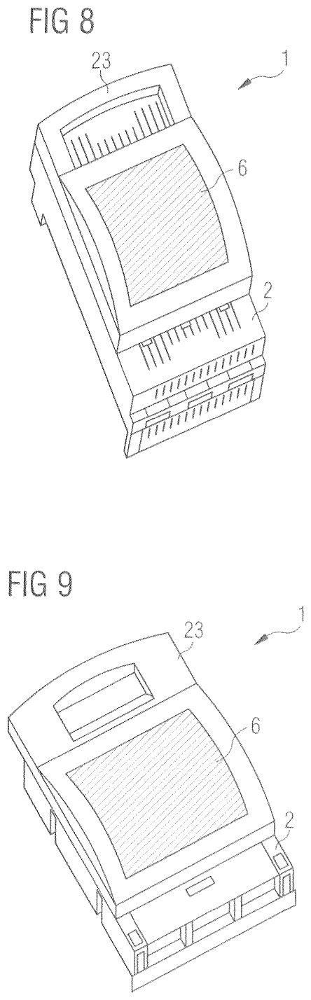

FIGS. 8, 9 show examples of possible low-voltage devices 1 with a flexible display unit 6 mounted in their housing 2. As shown in FIG. 8, in the housing 2 of the low-voltage device 1 there may also be ventilation slots for ventilating internal components. In the embodiment shown in FIG. 8, the flexible display unit 6 is attached to a display housing portion 5 of a handle 23 of the housing 2. FIG. 9 shows an NH-class fuse switch disconnector as an example of a low-voltage device 1.

The flexible display unit 6 may be integrated in or attached to the housing 2 of various low-voltage devices 1. These low-voltage devices 1 include, for example, a load-break switch with fuses, a fuse switch disconnector, a load-break switch, a circuit breaker, a motor control unit, a power supply unit, a frequency converter or a current feed-in module for current busbars. Depending on the functionality of the low-voltage device 1, different information may be shown to the user on the display surface of the flexible display unit 6 if required. In a preferred embodiment, the display unit 6 also comprises at least one integrated camera 7 for detecting the mounting environment. The display unit 6 comprises a display and touch function. Corresponding pressing surfaces for pressing a fingertip of the user thereto can be displayed on the flexible display unit 6. The camera 7 integrated in the display unit 6 may provide further functions in a possible embodiment. For example, in one possible implementation, the integrated camera 7 of the display unit 6 may also capture a user's biometric data, such as a fingerprint or the like. This can be used to authorize the user or installer to carry out maintenance and repair tasks on the switching cabinet or distribution board. The integration of the camera 7 within the flexible display unit 6 is optional. In an alternative embodiment, a separate camera 7 may also be provided next to the touch-sensitive display layer 6 in the housing 2 of the low-voltage device 1. An acoustic interface for inputting voice commands and for outputting warning signals can also be additionally integrated in the housing 2 of the low-voltage device 1. The various low-voltage devices 1 within the distribution board or switching cabinet can preferably exchange data with each other internally in real time via a bus system, wherein the data can be output to a user via a corresponding interface if required. By coupling the controller 17 of the low-voltage device 1 with an intranet or the Internet, it is also possible to carry out a remote diagnosis of the current operating status of the corresponding low-voltage device 1 and other devices provided in the surroundings of the low-voltage device 1. In one possible embodiment, the camera 7 constitutes a webcam for transmitting camera images to a remote server of the intranet or the Internet. This server is located, for example, at the manufacturer of the switching cabinet or low-voltage device 1. The flexible display unit 6 provided in the housing 2 of the low-voltage device 1 can support a technician or user in many ways, especially in carrying out repair and maintenance work. For example, IP addresses or other service numbers can also be displayed, which provide a direct ordering function for ordering accessories or spare parts. For example, in the event of a malfunction of a low-voltage device 1, not only the malfunction is displayed, but also operating instructions for rectifying the malfunction. If troubleshooting fails, then, in addition, a link to a website for ordering a corresponding replacement low-voltage device 1 may also be displayed, whereby the user can trigger an order process for ordering the replacement device by entering a corresponding order command on the touch-sensitive display surface of the display unit 6. This not only considerably speeds up the ordering of a spare part, but also prevents incorrect spare parts from being reordered.

1. A low-voltage device for electrical distribution boards and switching cabinet installations with components comprised in a housing of the low-voltage device, wherein the housing of the low-voltage device comprises:
a mounting interface for mounting the housing to a corresponding mating interface of the electrical distribution board or the switching cabinet or to a component installed in the electrical distribution board or in the switching cabinet;
a display housing portion of the housing, which is provided for a display unit of the low-voltage device and comprises one or more flexibly formed bendable and foldable display units, the flexible display unit being provided bent to fit a contour of the display housing portion of the housing of the low-voltage device, or folded on the display housing portion of the housing of the low-voltage device and is unfoldable there to enlarge a display surface of the display unit.

2. The low-voltage device according to claim 1, wherein the flexible display unit comprises a display layer with a thickness of preferably less than 1 mm.

3. The low-voltage device according to claim 1, wherein the flexible display unit comprises a display layer with a bending radius of preferably less than 10 mm.

4. The low-voltage device according to claim 1, wherein the flexible display unit comprises a touch-sensitive display layer for user input by a user and for displaying information to a user.

5. The low-voltage device according to claim 1, wherein the housing of the low-voltage device comprises a mounting interface for mounting the low-voltage device to at least one current busbar of a current busbar system of the switching cabinet and for electrically contacting the current busbar.

6. The low-voltage device according to claim 1, wherein the housing of the low-voltage device comprises a mounting interface for mounting the low-voltage device to a top-hat rail or to a mounting plate of the switching cabinet.

7. The low-voltage device according to claim 1, wherein the flexible display unit is detachably attached to a data interface provided on the display housing portion of the housing of the low-voltage device and/or to a power supply interface,
wherein the flexible display unit stays switched on after detachment from the housing of the low-voltage device, wherein data is exchanged via a wired or wireless data connection and wherein a power supply to the display unit detached from the housing of the low-voltage device is realized via a power connection or by an energy storage unit integrated in the display unit.

8. The low-voltage device according to claim 1, wherein the display housing portion of the housing of the low-voltage device consists of a transparent material in which the flexible display layer of the display unit is embedded.

9. The low-voltage device according to claim 1, wherein the flexible display layer of the display unit comprises an OLED display layer.

10. The low-voltage device according to claim 1, in which the components in the housing of the low-voltage device comprise components of the low-voltage device that generate heat during operation of the low-voltage device.

11. The low-voltage device according to claim 10, wherein the display housing portion of the housing of the low-voltage device provided for the flexible display unit or the display unit is thermally insulated from the power components of the low-voltage device by a thermal insulation for the protection of the flexible display unit.

12. The low-voltage device according to claim 1, wherein the components contained in the housing of the low-voltage device comprise a control unit, which exchanges data with the flexible display unit provided on the display housing portion via a data interface provided in the display housing portion of the housing of the low-voltage device.

13. The low-voltage device according to claim 1, wherein the components contained in the housing of the low-voltage device comprise a transceiver, which provides a wireless communication link with a control unit of the switching cabinet or of the electrical distribution board via a transceiver of the switching cabinet or the electrical distribution board.

14. The low-voltage device according to claim 1, wherein in the display area of the flexible display unit a camera is integrated, which generates camera images in the visible frequency range or in an invisible frequency range.

15. The low-voltage device according to claim 1, wherein the housing of the low-voltage device is made of an electrically insulating and fireproof material.

16. The low-voltage device according to claim 1, wherein the low-voltage device further comprises:
a load-break switch with fuses, a
fuse switch disconnector,
a switch disconnector,
a circuit breaker,
a motor control unit,
a power supply unit,
a frequency converter and/or
a power feed-in module.

17. The low-voltage device according to claim 1, wherein a data and control interface for connecting a capacitive, inductive or resistive load to the low-voltage device is provided in the housing of the low-voltage device.

18. The low-voltage device according to claim 1, wherein the information displayed on the flexible display unit of the low-voltage device comprises:
status information of the low-voltage device or other low-voltage devices mounted in the switching cabinet,
configuration details of the low-voltage device or other low-voltage devices mounted in the switching cabinet,
measurement data of the low-voltage device or other low-voltage devices mounted in the switching cabinet,
a circuit diagram of the low-voltage device and/or another low-voltage device mounted in the switching cabinet or a circuit diagram of the low-voltage devices mounted in the switching cabinet,
operating instructions for operating the low-voltage device or the switching cabinet,
a service number for a maintenance service for servicing the switching cabinet and/or the low-voltage device or other low-voltage devices within the switching cabinet and/or
status information of a load connected to the low-voltage device.

19. The low-voltage device according to claim 1, wherein the unfolded flexible display unit is pivotably attached to the housing of the low-voltage device.

20. The low-voltage device according to claim 1, wherein an unfolded flexible display unit of the low-voltage device forms, together with another unfolded flexible display unit of a low-voltage device mounted adjacently on the rail of the switching cabinet, a composite display unit with a large display area.

21. The low-voltage device according to claim 1, wherein the low-voltage device comprises a control unit integrated into the housing, wherein the control unit is connected to the display unit and to a camera via a data and control interface.

22. The low-voltage device according to claim 21, wherein the control unit comprises an artificial intelligence module for classifying the image data provided by the camera.

23. The low-voltage device according to claim 1, wherein the display unit of the low-voltage device is connected via a wired or wireless bus system of the switching cabinet with other devices of the switching cabinet, in particular with other low-voltage devices of the switching cabinet, for data transmission.

24. The low-voltage device according to claim 1, wherein the display unit of the low-voltage device is connected to an intranet of an automation system and/or to the Internet via a gateway.

25. The low-voltage device according to claim 1, wherein the display unit is coupled to a user interface of the low-voltage device and/or of the switching cabinet.

26. The low-voltage device according to claim 1, wherein the flexible display unit comprises a flexible rear support layer for supporting the display layer of the display unit and a flexible front transparent protective layer for protecting the display layer of the display unit.

27. The low-voltage device according to claim 1, wherein the display unit can be folded along at least one folding line with a certain bending radius in each case.

28. A switching cabinet comprising:
rails and/or mounting plates; and
at least one low-voltage device according to claim 1 mounted on said rails and/or mounting plates.
